(19) United States
(12) Patent Application Publication
(10) Pub. No.: US 2026/0148904 A1
(43) Pub. Date: May 28, 2026

(54) CAPACITOR STRUCTURE AND MANUFACTURING METHOD THEREOF

(71) Applicant: NANYA TECHNOLOGY CORPORATION, New Taipei City (TW)

(72) Inventor: Chih-Hsiung Huang, New Taipei City (TW)

(73) Assignee: NANYA TECHNOLOGY CORPORATION, New Taipei City (TW)

(21) Appl. No.: 18/957,837

(22) Filed: Nov. 24, 2024

(51) Int. Cl. H01G 4/33; H01G 2/06; H01G 4/008; H01G 4/12

(52) U.S. Cl. CPC H01G 4/33; H01G 2/065; H01G 4/008; H01G 4/1236

(57) ABSTRACT

A capacitor structure and a manufacturing method thereof are provided. The capacitor structure includes a bottom electrode, an insulation layer, a top electrode and an interfacial layer. The insulation layer is disposed on the bottom electrode. The top electrode is disposed over the insulation layer. The interfacial layer is disposed between the insulation layer and the top electrode. A composition of the interfacial layer has at least one element in common with elements containing in the insulation layer and at least one element in common with elements containing in the top electrode.

### BACKGROUND

### Technical Field

The present invention relates to a semiconductor device, and in particular to a capacitor structure in the semiconductor device and a manufacturing method thereof.

### Description of Related Art

A semiconductor device, such as a dynamic random-access memory (DRAM), requires high capacitance for data saving and reading. As the demand of scaling down the semiconductor device increases, an aspect ratio of the capacitor structure becomes higher, which may affect the step coverage rate of a top electrode of the capacitor structure and thereby may reduce the capacitance of the capacitor structure.

### SUMMARY

The present invention provides a capacitor structure and a manufacturing method thereof, which has improved electrical performance.

The capacitor structure of the present invention includes a bottom electrode, an insulation layer, a top electrode and an interfacial layer. The insulation layer is disposed on the bottom electrode. The top electrode is disposed over the insulation layer. The interfacial layer is disposed between the insulation layer and the top electrode. A composition of the interfacial layer has at least one element in common with elements containing in the insulation layer and at least one element in common with elements containing in the top electrode.

In an embodiment of the capacitor structure of the present invention, a material of the interfacial layer includes TiOₓN_{y}, where 0<x≤1 and x+y=1.

In an embodiment of the capacitor structure of the present invention, an oxygen concentration of the interfacial layer is higher than an oxygen concentration of the top electrode.

In an embodiment of the capacitor structure of the present invention, a nitrogen concentration of the interfacial layer is lower than a nitrogen concentration of the top electrode.

In an embodiment of the capacitor structure of the present invention, the interfacial layer includes a first interfacial layer and a second interfacial layer. The first interfacial layer is disposed between the insulation layer and the top electrode. The second interfacial layer is disposed between the first interfacial layer and the top electrode. An oxygen concentration of the first interfacial layer is higher than an oxygen concentration of the second interfacial layer.

In an embodiment of the capacitor structure of the present invention, a nitrogen concentration of the first interfacial layer is lower than a nitrogen concentration of the second interfacial layer.

In an embodiment of the capacitor structure of the present invention, a thickness of the interfacial layer is in a range of 1 Å to 30 Å.

In an embodiment of the capacitor structure of the present invention, materials of the top electrode and the bottom electrode includes TiN, and a material of the insulation layer includes a high-k dielectric material.

In an embodiment of the capacitor structure of the present invention, the bottom electrode is doped with Si.

In an embodiment of the capacitor structure of the present invention, the insulation layer includes hafnium oxide, aluminum oxide, zirconium oxide, silicon oxide, lanthanum oxide or magnesium oxide.

The manufacturing method of the capacitor structure of the present invention includes the following steps. A bottom electrode is formed. An insulation layer is formed on the bottom electrode. An interfacial layer is formed on the insulation layer. A top electrode is formed on the interfacial layer. A composition of the interfacial layer has at least one element in common with elements containing in the insulation layer and at least one element in common with elements containing in the top electrode.

In an embodiment of the manufacturing method of the capacitor structure of the present invention, the interfacial layer is formed by atomic layer deposition, and the interfacial layer and the top electrode have a common element, N.

In an embodiment of the manufacturing method of the capacitor structure of the present invention, a nitrogen concentration of the interfacial layer is lower than a nitrogen concentration of the top electrode.

In an embodiment of the manufacturing method of the capacitor structure of the present invention, forming the interfacial layer includes the following steps. A first interfacial layer is formed on the insulation layer. A second interfacial layer is formed on the first interfacial layer. An oxygen concentration of the first interfacial layer is higher than an oxygen concentration of the second interfacial layer.

In an embodiment of the manufacturing method of the capacitor structure of the present invention, forming the bottom electrode and the insulation layer includes the following steps. A stack structure is formed over a substrate, wherein the stack structure includes support layers and sacrificial layers stacked alternatively. Openings penetrating through the stack structure are formed. The bottom electrode is deposited on sidewalls of the openings and a portion of the substrate exposed by the openings. The sacrificial layers of the stack structure are removed to expose a portion of the bottom electrode and the support layers. The insulation layer is deposited on exposed surfaces of the bottom electrode and the support layers.

Based on the above, the capacitor structure of the present application includes an interfacial layer between the insulation layer and the top electrode, which can improve the step coverage rate of the top electrode and thereby improve the electrical performance of the capacitor structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to 4, FIG. 5A, FIG. 5B, FIG. 6A, FIG. 6B, FIG. 7A, FIG. 7B and FIG. 8 to FIG. 11 are schematic views of the manufacturing method of a capacitor structure according to an embodiment of the present invention.

FIG. 12 is a schematic cross-sectional view of a capacitor structure according to another embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

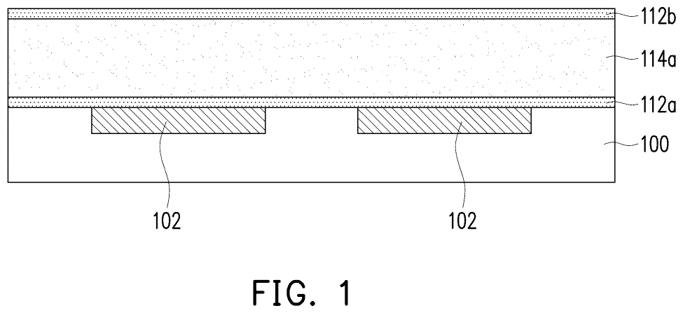

FIG. 1 to 4, FIG. 5A, FIG. 6A, FIG. 7A and FIG. 8 to FIG. 11 are schematic cross-sectional views of the manufacturing method of a capacitor structure according to an embodiment of the present invention. FIG. 5B is a schematic top view of FIG. 5A, and FIG. 5A is illustrated along a cutting line A-A′ of FIG. 5B. FIG. 6B is a schematic top view of FIG. 6A, and FIG. 6A is illustrated along a cutting line B-B′ of FIG. 6B. FIG. 7B is a schematic top view of FIG. 7A, and FIG. 7A is illustrated along a cutting line C-C′ of FIG. 7B.

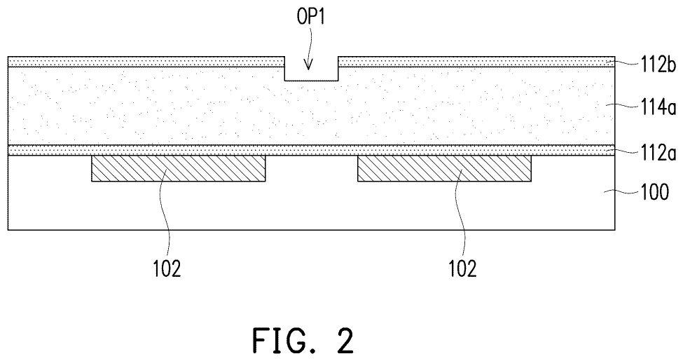

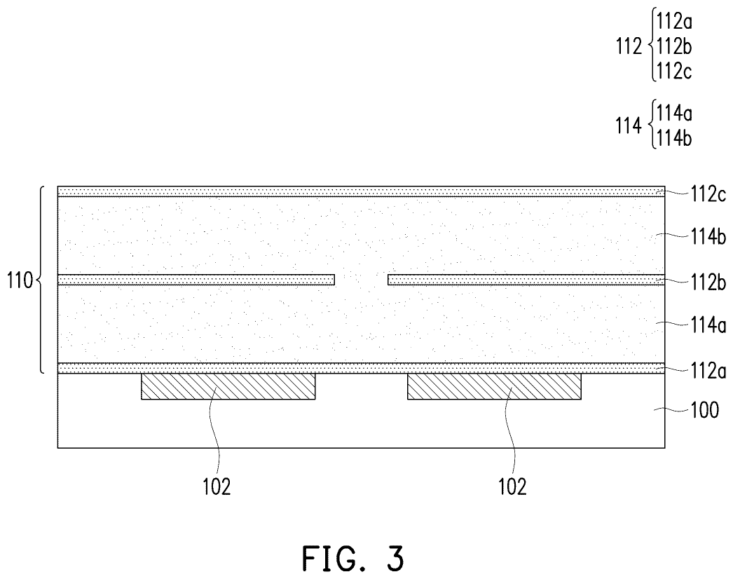

Referring to FIG. 1 to FIG. 3, a stack structure 110 is formed on a substrate 100, wherein the stack structure 110 comprises support layers 112 (including a first support layer 112a, a second support layer 112b and a third support layer 112c) and sacrificial layers 144 (including a first sacrificial layer 114a and a second sacrificial layer 114b) stacked alternatively on the substrate 100. For example, in FIG. 1, a first support layer 112a, a first sacrificial layer 114a and a second support layer 112b are sequentially formed on the substrate 100. Then, in FIG. 2, a first opening OP1 is formed in the second support layer 112b to expose the underlying first sacrificial layer 114a. In some embodiments, the first opening OP1 is formed by an etching process to remove a portion of the second support layer 112b. In some embodiments, a portion of the first sacrificial layer 114a may be removed during the etching process. In some embodiments, the etching process may be a wet etching or a dry etching process, which is not limited thereto. In FIG. 3, a second sacrificial layer 114b and a third support layer 112c are sequentially formed on the second support layer 112b. In some embodiments, the second sacrificial layer 114b extends into the first opening OP1, such that the second sacrificial layer 114b is in direct contact with the first sacrificial layer 114a. In other embodiments, the first opening OP1 may not be formed during the forming of the stack structure 110.

In some embodiments, the support layers 112 (including a first support layer 112a, a second support layer 112b and a third support layer 112c) and the sacrificial layers 144 (including a first sacrificial layer 114a and a second sacrificial layer 114b) may be formed by chemical vapor deposition (CVD) method, physical vapor deposition (PVD) method or other suitable methods, which is not limited. In some embodiments, a material of the support layer 112 include nitride or other suitable materials. In some embodiments, a material of the sacrificial layers 144 include oxide or other suitable materials.

In some embodiments, the substrate 100 includes landing pads 102 and transistors (not shown) electrically connected with the corresponding landing pads 102. In some embodiments, a material of the landing pads 102 include copper, aluminum, tungsten, gold, silver, alloy of the aforementioned materials or other suitable conductive materials. In some embodiments, the substrate 100 further includes driving circuits (such as bit lines, word line or the like) (not shown) electrically connected with the transistors.

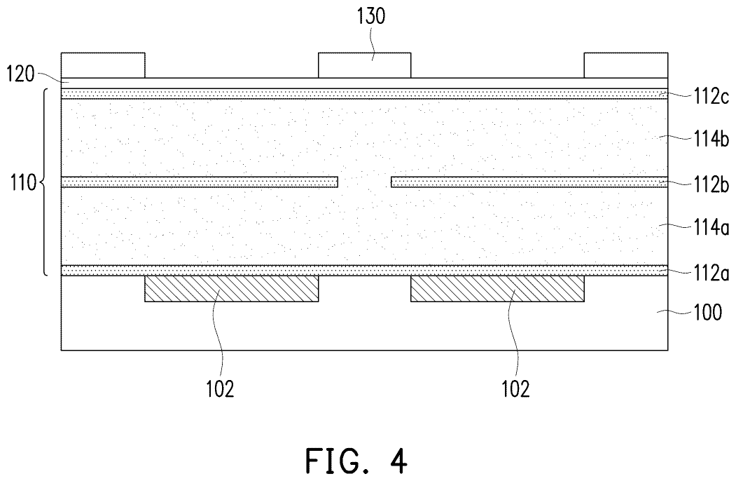

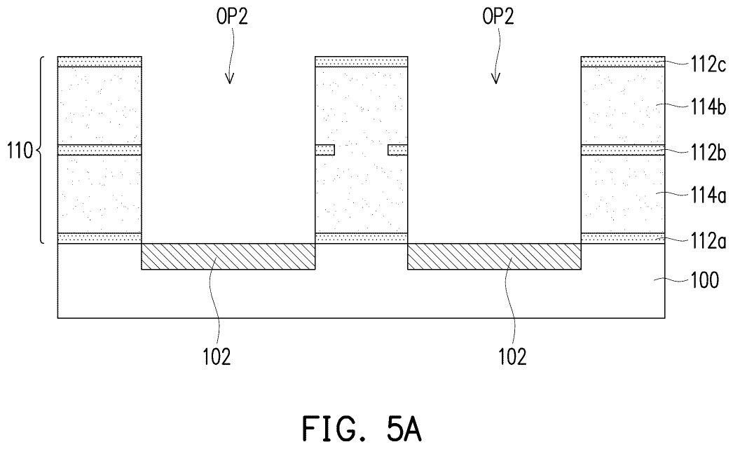

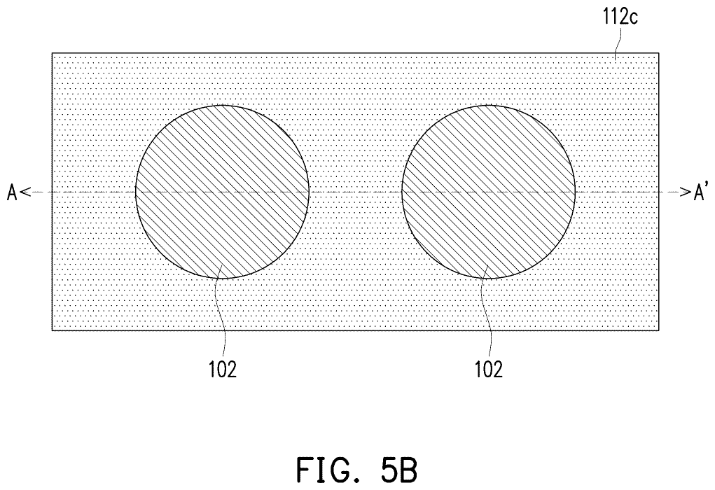

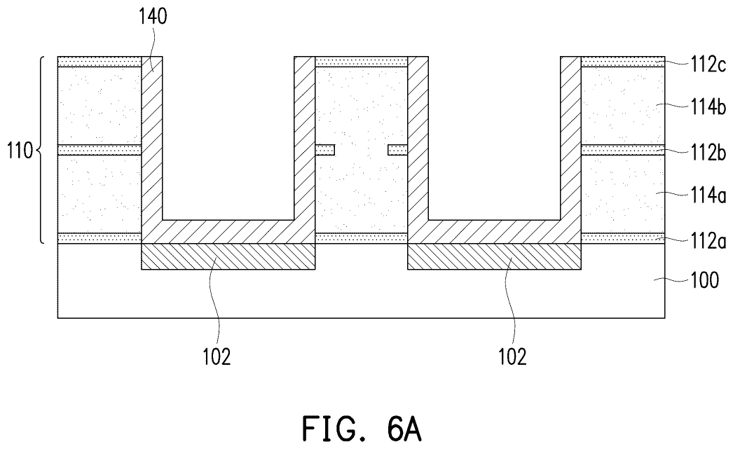

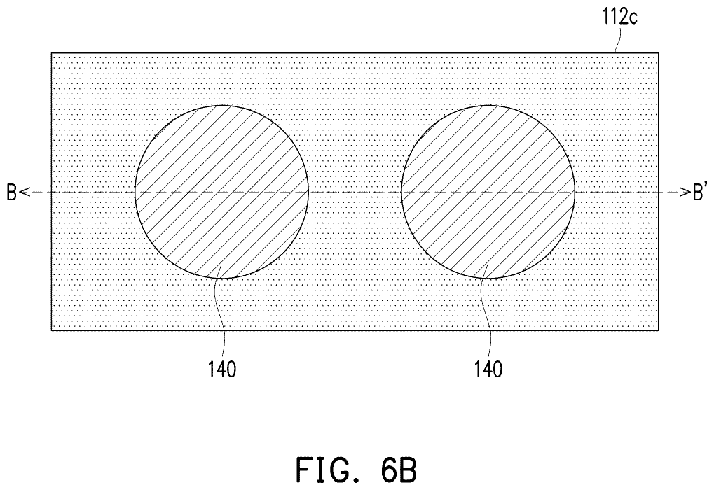

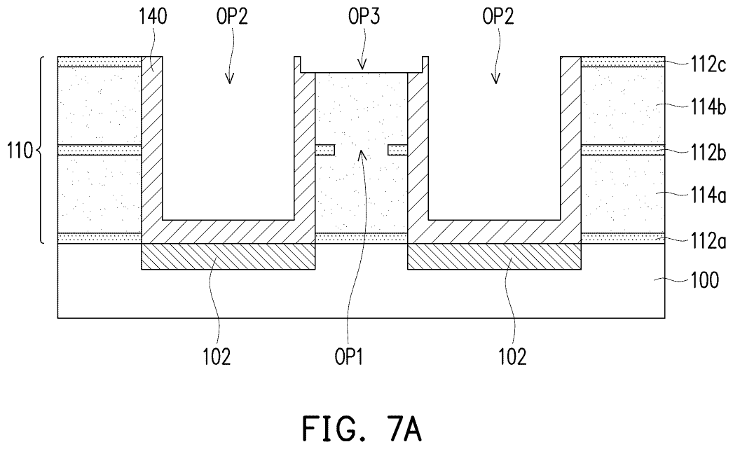

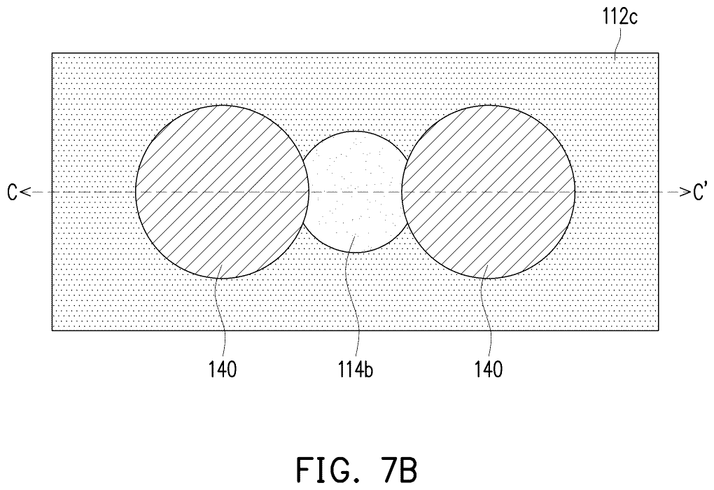

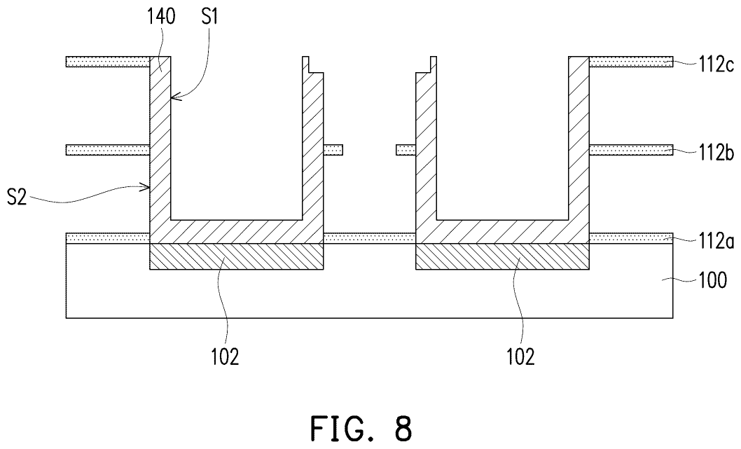

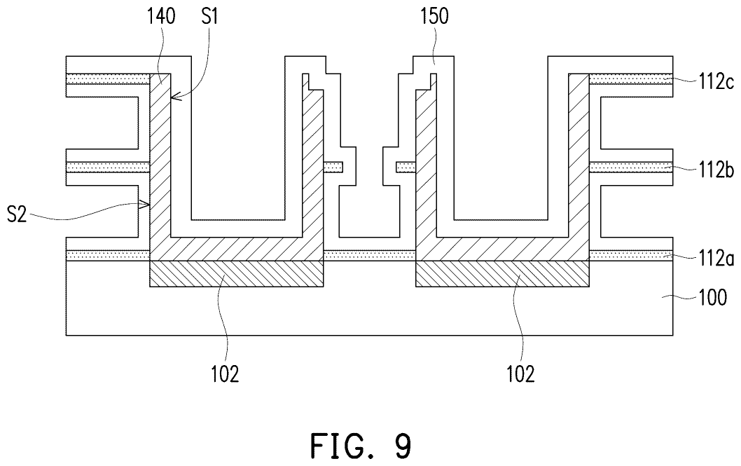

Referring to FIG. 4, a hard mask layer 120 is formed on the stack structure 110 by chemical vapor deposition (CVD) method, physical vapor deposition (PVD) method or other suitable methods. Then, a patterned photoresist layer 130 is formed on the hard mask layer 120 to define locations of the second openings subsequently formed. For example, a photoresist material layer (not shown) is formed on the hard mask layer 120 by spin coating, slit coating, slit-spin coating or other suitable methods, and then using a photomask with a design pattern, an exposure process is performed on the photoresist material layer to form the patterned photoresist layer 130.

Referring to FIG. 5A and FIG. 5B, second openings OP2 penetrating through the stack structure 100 are formed to expose the landing pads 102. For example, using the patterned photoresist layer 120 as an etching mask, the hard mask layer 120 is patterned to transfer the pattern of the patterned photoresist layer 130 to the hard mask layer 120. Then, the photoresist layer 130 is removed by an ashing process, an etching process or other suitable methods. Afterwards, using the patterned hard mask layer 120 as an etching mask, one or more etching processes are performed to remove a portion of the stack structure 110 until the landing pads 102 are exposed and thereby the second openings OP2 are formed in the stack structure 110. Then, the hard mask layer 102 is removed.

Referring to FIG. 6A and FIG. 6B, a bottom electrode 140 is formed on the stack structure 110. For example, a conductive layer is deposited on a top surface of the stack structure 110, sidewalls of the second openings OP2 and a portion of the substrate 100 exposed by the second openings OP2 (that is, the landing pads 102). In some embodiments, the conductive layer is formed by chemical vapor deposition (CVD) method, physical vapor deposition (PVD) method, atomic layer deposition (ALD) method, plating process or other suitable methods. In some embodiments, the conductive layer or the bottom electrode 140 is conformally formed on the stack structure 110. Then, a planarization process is performed until the top surface of the stack structure 110 is exposed and thereby the bottom electrode 140 is formed. That is to say, a portion of the conductive layer formed on the third support layer 112c is removed during the planarization process. In some embodiments, the planarization process may include a chemical mechanical polishing process, mechanical grinding process or other suitable processes.

In some embodiments, a material of the conductive layer or the bottom electrode 140 includes titanium nitride (TiN). In some embodiments, the bottom electrode 140 is doped with silicon (Si) to increase a hardness of the bottom electrode 140 and reduce the possibility of being etched during the subsequent removal process of the sacrificial layer 114. In an embodiment that the bottom electrode 140 is doped with silicon, the bottom electrode 140 may include titanium silicon nitride (TiSiN). However, the material of the bottom electrode 140 is not limited in the present invention. In other embodiments, a material of the conductive layer may include metal (such as copper (Cu), tungsten (W), gold (Au), silver (Ag), titanium (Ti), aluminum (Al) or the like) or other suitable conductive materials.

In some embodiments, a thickness of the bottom electrode 140 is in a range of 2 nm to 10 nm, but it is not limited thereto.

Referring to FIG. 7A and FIG. 7B, a portion of the third support layer 112c is removed to form a third opening OP3 in the third support layer 112c and to expose the underlying second sacrificial layer 114b. In some embodiments, the third opening OP3 is formed by an etching process to remove a portion of the third support layer 112c. In some embodiments, a portion of the second sacrificial layer 114b and a portion of the bottom electrode 140 are removed during the etching process. In some embodiments, an orthogonal projection of the third opening OP3 on the substrate 100 is overlapped with an orthogonal projection of the first opening OP1 on the substrate 100. In some embodiments, the first opening OP1 and the third opening OP3 are located between the adjacent second openings OP2.

Referring to FIG. 8, the sacrificial layers 114 are removed by an etching process which selectively etches the sacrificial layers 114 but not or almost not etches the support layers 112 and the bottom electrode 140. Since the second sacrificial layer 114b is exposed by the third opening OP3 and the first opening OP1 is formed in the second support layer 112b, the first sacrificial layer 114a and the second sacrificial layer 114b can be removed in the same process step.

In an embodiment where the first opening OP1 is not formed during the forming of the stack structure 110, the first sacrificial layer 114a and the second sacrificial layer 114b may be removed in different process steps. For example, a first etching process is performed to remove the second sacrificial layer 114b. Then, the first opening OP1 is formed in the second support layer 112b after the removal of the second sacrificial layer 114b. Thereafter, a second etching process is performed to remove the first sacrificial layer 114a.

After the sacrificial layers 114 are removed, a space between the adjacent support layers 112 is released and a portion of an outer surface S2 of the bottom electrode 140 are exposed. The outer surface S2 is opposite to the inner surface S1 and the outer surface S2 is connected directly with the support layers 112 and the landing pads 102. Also, the support layers 112 (including the first support layer 112a, the second support layer 112b and the third support layer 112c) are exposed after the removal of the sacrificial layers 114.

Referring to FIG. 9, an insulation layer 150 is formed on the bottom electrode 140. For example, the insulation layer 150 is formed by ALD method or other suitable methods. In some embodiments, the insulation layer 150 is conformally formed over the substrate 100, so that the insulation layer 150 is disposed on the exposed surfaces of the bottom electrode 140 (such as the inner surface S1 and the outer surface S2) and the exposed surfaces of the support layers 112.

In some embodiments, the insulation layer 150 includes a high-k dielectric material whose dielectric constant is greater than or equal to the dielectric constant of silicon oxide. For example, a material of the insulation layer 150 includes hafnium oxide, aluminum oxide, zirconium oxide, silicon oxide, lanthanum oxide, magnesium oxide or other suitable high-k materials.

In some embodiments, a thickness of the insulation layer 150 is in a range of 3 nm to 7 nm, but it is not limited thereto.

Referring to FIG. 10, an interfacial layer 160 is formed on the insulation layer 150. For example, the interfacial layer 160 is formed by ALD method or other suitable methods. In some embodiments, the interfacial layer 160 is conformally formed over the substrate 100, so that the interfacial layer 160 extends along a surface of the insulation layer 150.

In some embodiments, a composition of the interfacial layer 160 has at least one element in common with elements containing in the insulation layer 150. In this way, the interfacial layer 160 can be easily formed on the insulation layer 150, so that the interfacial layer 160 has a good step coverage rate. For example, the interfacial layer 160 and the insulation layer 150 have a common element, O.

In some embodiments, a composition of the interfacial layer 160 has at least one element in common with elements containing in the top electrode subsequently formed (for example, top electrode 170 described later), such that the top electrode can be easily formed on the interfacial layer 160 in the subsequent process.

In some embodiments, a material of the interfacial layer 160 includes TiOₓN_{y}, where 0<x≤1 and x+y=1.

In some embodiments, a thickness of the interfacial layer 160 is in a range of 1 Å to 30 Å. In this way, the interfacial layer 160 can effectively improve the step coverage of the top electrode subsequently formed without significantly affecting the space for forming the top electrode.

Referring to FIG. 11, a top electrode 170 is formed on the interfacial layer 160. For example, the top electrode 170 is formed by ALD method or other suitable methods. In some embodiments, the top electrode 170 is conformally formed over the substrate 100, so that the top electrode 170 extends along a surface of the interfacial layer 160.

In some embodiments, a material of the top electrode 170 includes titanium nitride (TiN). Since the composition of the interfacial layer 160 has at least one element (such as Ti or N) in common with elements containing in the top electrode 170, compared with the top electrode 170 is directly formed on the insulation layer 150, the top electrode 170 can be easily formed on the interfacial layer 160, and thereby a step coverage of the top electrode 170 is improved.

In some embodiments, a thickness of the top electrode 170 is in a range of 1 nm to 5 nm. In some embodiments, the top electrode 170 may fill the remaining space released by the sacrificial layers 114 and the openings.

Based on the above, the forming of a capacitor structure 10 is substantially completed.

Referring to FIG. 11, the capacitor structure 10 includes a bottom electrode 140, an insulation layer 150, an interfacial layer 160 and a top electrode 170. The insulation layer 150 is disposed on the bottom electrode 140. The top electrode 170 is disposed over the insulation layer 150. The interfacial layer 160 is disposed between the insulation layer 150 and the top electrode 170. A composition of the interfacial layer 160 has at least one element in common with elements containing in the insulation layer 150 and at least one element in common with elements containing in the top electrode 170. Since the composition of the interfacial layer 160 has at least one element in common with elements containing in the top electrode 170, the step coverage rate of the top electrode 170 can be improved and thereby the electrical performance of the capacitor 10 is improved.

In some embodiments, materials of the top electrode 170 and the bottom electrode 140 comprises TiN, and a material of the insulation layer 150 comprises a high-k dielectric material.

In some embodiments, a material of the interfacial layer 160 is different from a material of the insulation layer 150. In some embodiments, a material of the interfacial layer 160 includes TiOₓN_{y}, where 0<x≤1 and x+y=1.

In some embodiments, a nitrogen concentration of the interfacial layer 160 is lower than a nitrogen concentration of the top electrode 170 and an oxygen concentration of the interfacial layer 160 is higher than an oxygen concentration of the top electrode 170.

In some embodiments, a thickness of the interfacial layer 160 is smaller than a thickness of the insulation layer 150. In some embodiments, a thickness of the interfacial layer 160 is smaller than a thickness of the top electrode 170.

In some embodiments, the bottom electrode 140 of the capacitor structure 10 is surrounded by support layers 112. In some embodiments, the support layers 112 includes a first support layer 112a, a second support layer 112b and a third support layer 112c. The second support layer 112b is located between the first support layer 112a and the third support layer 112c. The first support layer 112a surrounds around a lower portion of the bottom electrode 140. The second support layer 112b surrounds around a middle portion of the bottom electrode 140. The third support layer 112c surrounds around a upper portion of the bottom electrode 140.

In some embodiments, the insulation layer 150 further extends onto the support layers.

In some embodiments, the capacitor structure 10 is disposed on a substrate 100 and electrically connected with the substrate 100. In some embodiments, the substrate 100 includes landing pads 102 and transistors (not shown) electrically connected with the corresponding landing pads 102. The capacitor structure 10 may be electrically connected to the corresponding transistors through the corresponding landing pads 102 to form memory cells, such as DRAM cells or the like.

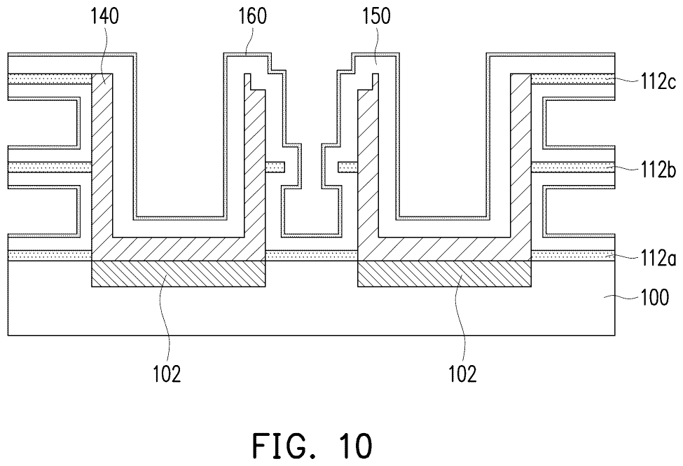

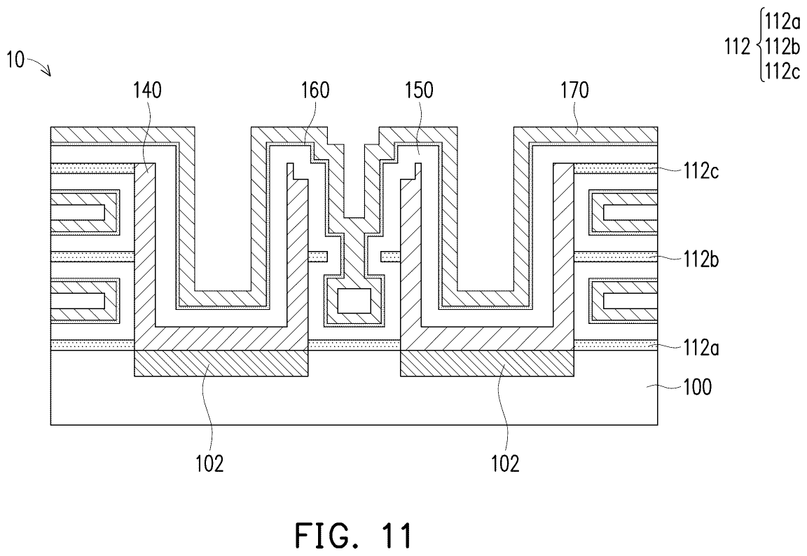

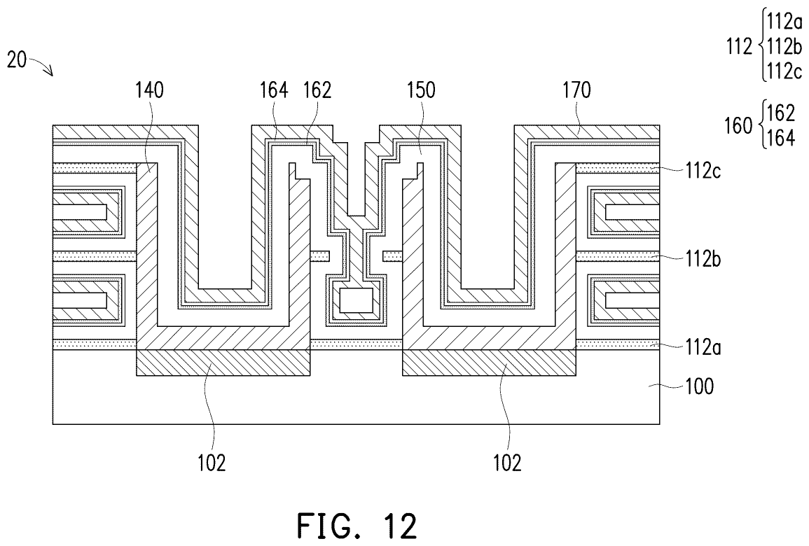

FIG. 12 is a schematic cross-sectional view of a capacitor structure according to another embodiment of the present invention. It must be noted here that the embodiment in FIG. 12 continues to use the referential numbers of the elements and a part of the contents of the embodiments of FIG. 11, wherein the same or similar referential numbers are used to denote the same or similar elements, and the description of the same technical contents is omitted. For the description of the omitted part, reference may be made to the foregoing embodiments, and details are not repeated here.

Referring to FIG. 12, the main difference between a capacitor structure 20 of the embodiment and the capacitor structure 10 is that the interfacial layer 160 of the capacitor structure 20 has a multi-layer structure. Each layer of the multi-layer structure has the same material but different ratios of composition. For example, an oxygen concentration of a layer of the multi-layer structure close to the insulation layer 150 is higher than an oxygen concentration of a layer of the multi-layer structure close to the top electrode 170. In other words, an oxygen concentration of the multi-layer structure gradually decreases from a side close to the insulation layer 150 to another side close to the top electrode 170. In some embodiments, a nitrogen concentration of a layer of the multi-layer structure close to the insulation layer 150 is lower than a nitrogen concentration of a layer of the multi-layer structure close to the top electrode 170. In other words, a nitrogen concentration of the multi-layer structure gradually increases from a side close to the insulation layer 150 to another side close to the top electrode 170. Since the interfacial layer 160 has a multi-layer structure, the multi-layer structure could gradually change its composition to accommodate different materials of the insulation layer 150 and the top electrode 170, such that the step coverage rate of the interfacial layer 160 and the top electrode 170 may be improved.

In some embodiments, the interfacial layer 160 includes a first interfacial layer 162 and a second interfacial layer 164. The first interfacial layer 162 is disposed between the insulation layer 150 and the top electrode 170. The second interfacial layer 164 is disposed between the first interfacial layer 162 and the top electrode 170. In some embodiments, the forming of the interfacial layer 160 includes the following steps. First, a first interfacial layer 162 is deposited on the insulation layer 150, and then a second interfacial layer 164 is deposited on the first interfacial layer 162. The first interfacial layer 162 and the second interfacial layer 164 may be formed by ALD method or other suitable methods.

In some embodiments, the first interfacial layer 162 and the second interfacial layer 164 include TiOₓN_{y}. An oxygen concentration of the first interfacial layer 162 is higher than an oxygen concentration of the second interfacial layer 164. For example, the first interfacial layer 162 may be TiO_{0.5}N_{0.5,} and the second interfacial layer 164 may be TiO_{0.25}N_{0.75.} In some embodiments, a nitrogen concentration of the first interfacial layer 162 is lower than a nitrogen concentration of the second interfacial layer 164.

In some embodiments, thicknesses of the first interfacial layer 162 and the second interfacial layer 164 are not limited, as long as a total thickness of the interfacial layer 160 is in a range of 1 Å to 30 Å.

Please note that a two-layer structure is illustrated for the interfacial layer 160 in FIG. 12, but the present invention is not limited thereto. The number of layers of the interfacial layer 160 can be adjusted depending on the actual demand.

Based on the above, the capacitor structure of the present application includes an interfacial layer between the insulation layer and the top electrode, which can improve the step coverage rate of the top electrode and thereby improve the electrical performance of the capacitor structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A capacitor structure, comprising:
a bottom electrode;
an insulation layer disposed on the bottom electrode;
a top electrode disposed over the insulation layer; and
an interfacial layer disposed between the insulation layer and the top electrode, wherein a composition of the interfacial layer has at least one element in common with elements containing in the insulation layer and at least one element in common with elements containing in the top electrode.

2. The capacitor structure of claim 1, wherein a material of the interfacial layer comprises TiOₓN_{y}, where 0<x≤1 and x+y=1.

3. The capacitor structure of claim 2, wherein an oxygen concentration of the interfacial layer is higher than an oxygen concentration of the top electrode.

4. The capacitor structure of claim 2, wherein a nitrogen concentration of the interfacial layer is lower than a nitrogen concentration of the top electrode.

5. The capacitor structure of claim 1, wherein the interfacial layer comprises:
a first interfacial layer disposed between the insulation layer and the top electrode; and
a second interfacial layer disposed between the first interfacial layer and the top electrode, wherein an oxygen concentration of the first interfacial layer is higher than an oxygen concentration of the second interfacial layer.

6. The capacitor structure of claim 5, wherein a nitrogen concentration of the first interfacial layer is lower than a nitrogen concentration of the second interfacial layer.

7. The capacitor structure of claim 1, wherein a thickness of the interfacial layer is in a range of 1 Å to 30 Å.

8. The capacitor structure of claim 1, wherein materials of the top electrode and the bottom electrode comprises TiN, and a material of the insulation layer comprises a high-k dielectric material.

9. The capacitor structure of claim 8, wherein the bottom electrode is doped with Si.

10. The capacitor structure of claim 8, wherein the insulation layer comprises hafnium oxide, aluminum oxide, zirconium oxide, silicon oxide, lanthanum oxide or magnesium oxide.

11. A manufacturing method of a capacitor structure, comprising:
forming a bottom electrode;
forming an insulation layer on the bottom electrode;
forming an interfacial layer on the insulation layer; and
forming a top electrode on the interfacial layer, wherein a composition of the interfacial layer has at least one element in common with elements containing in the insulation layer and at least one element in common with elements containing in the top electrode.

12. The manufacturing method of claim 11, wherein the interfacial layer is formed by atomic layer deposition, and the interfacial layer and the top electrode have a common element, N.

13. The manufacturing method of claim 12, wherein a nitrogen concentration of the interfacial layer is lower than a nitrogen concentration of the top electrode.

14. The manufacturing method of claim 11, wherein forming the interfacial layer comprises:
forming a first interfacial layer on the insulation layer; and
forming a second interfacial layer on the first interfacial layer, wherein an oxygen concentration of the first interfacial layer is higher than an oxygen concentration of the second interfacial layer.

15. The manufacturing method of claim 11, wherein forming the bottom electrode and the insulation layer comprises:
forming a stack structure over a substrate, wherein the stack structure comprises support layers and sacrificial layers stacked alternatively;
forming openings penetrating through the stack structure;
depositing the bottom electrode on sidewalls of the openings and a portion of the substrate exposed by the openings;
removing the sacrificial layers of the stack structure to expose a portion of the bottom electrode and the support layers; and
depositing the insulation layer on exposed surfaces of the bottom electrode and the support layers.
